(19) United States
(12) Patent Application Publication
(10) Pub. No.: US 2016/0172456 A1
(43) Pub. Date: Jun. 16, 2016

(54) HIGH RESISTANCE METAL ETCH-STOP PLATE FOR METAL FLYOVER LAYER

(71) Applicant: QUALCOMM Incorporated, San Diego, CA (US)

(72) Inventors: Xia Li, San Diego, CA (US); John Jianhong Zhu, San Diego, CA (US); Jeffrey Junhao Xu, San Diego, CA (US); Bin Yang, San Diego, CA (US); Jun Yuan, San Diego, CA (US); Yu Lu, San Diego, CA (US)

(21) Appl. No.: 14/567,925

(22) Filed: Dec. 11, 2014

(51) Int. Cl. H01L 29/417; H01L 21/283

(52) U.S. Cl. CPC H01L 29/41775; H01L 21/283

(57) ABSTRACT

A semiconductor device includes a transistor having a metal gate, a source, and a drain. The semiconductor device also includes a high resistance metal etch-stop layer positioned above the metal gate of the transistor. The semiconductor device also includes a metal layer formed on the high resistance metal etch-stop layer. The metal layer is positioned above at least one of the source of the transistor or the drain of the transistor.

### I. FIELD

The present disclosure is generally related to a metal flyover layer.

### II. DESCRIPTION OF RELATED ART

Advances in technology have resulted in smaller and more powerful computing devices. For example, a variety of portable personal computing devices, including wireless telephones such as mobile and smart phones, tablets, and laptop computers, are small, lightweight, and easily carried by users. These devices can communicate voice and data packets over wireless networks. Further, many such devices incorporate additional functionalities such as a digital still camera, a digital video camera, a digital recorder, and an audio file player. Also, such devices can process executable instructions, including software applications, such as a web browser application, that can be used to access the Internet. As such, these devices can include significant computing capabilities.

Wireless telephones may include processing components (e.g., digital signal processors (DSPs), central processing units (CPUs), controllers, etc.) and memory components (e.g., magnetic random access memory (MRAM) devices, dynamic random access memory (DRAM) devices, etc.) that are operable to perform various tasks and applications. The processing components and the memory components may include one or more transistors (e.g., metal oxide semiconductor (MOS) transistors).

A conventional transistor may include a source, a drain, and a metal gate. The source, the drain, and the metal gate may be coupled to other transistors or to other circuit components (e.g., capacitors, inductors, resistors, etc.) via one or more metal layers. Using multiple metal layers may increase die area (e.g., increase cell size area). However, using a single metal layer positioned above the metal gate and at least one of the source or the drain (e.g., a “flyover” metal layer) may degrade process controls. For example, the single metal layer may short the metal gate if the single metal layer is in contact with, or within a relatively close proximity of, the metal gate.

### III. SUMMARY

Systems, methods, and techniques are disclosed for forming a high resistance metal etch-stop plate for a metal flyover layer. A semiconductor device (e.g., a transistor) may include a source, a drain, and a metal gate. A channel region (e.g., a source-channel-drain region formed within a substrate of the semiconductor device according to a fin-type field effect transistor (FinFET) technology)) may be electrically isolated from the metal gate via a high dielectric constant (HK) material. For example, the HK material may be formed on the channel region, and the metal gate may be formed on top of the HK material. A silicon nitride (SiN) layer may be formed on the metal gate and across (e.g., on top of) the source and the drain of the semiconductor device. One or more metal contacts may be formed to contact the source and the drain. Other circuit elements (e.g., transistors, inductors, capacitors, resistors, etc.) may be electrically coupled to the source and/or to the drain via the one or more metal contacts and a metal layer (e.g., a MO layer or a “flyover” layer). For example, the flyover layer may operate as an inter-device contact that couples the source and/or the drain to the other circuit elements.

A high resistance metal etch-stop layer may be formed on a portion of the SiN layer that is on top of the metal gate. In a particular aspect, the high resistance metal etch-stop layer may be comprised of titanium nitride (TiN). The flyover layer may be formed on top of the high resistance metal etch-stop layer and on top of the one or more metal contacts. Thus, the high resistance metal etch-stop layer may prevent the flyover layer from contacting, or coming within a relatively close proximity of, the metal gate. As a result, the high resistance metal etch-stop layer may substantially prohibit the flyover layer from providing an electrical short to the metal gate. For example, the high resistance metal etch-stop layer may electrically isolate the metal gate from the flyover layer to enable bias control of the metal gate.

In a particular aspect, a semiconductor device includes a transistor having a metal gate, a source, and a drain. The semiconductor device also includes a high resistance metal etch-stop layer positioned above the metal gate of the transistor. The semiconductor device also includes a metal layer formed on the high resistance metal etch-stop layer. The metal layer is positioned above at least one of the source of the transistor or the drain of the transistor.

In another particular aspect, a method includes depositing a high resistance metal etch-stop layer above a metal gate of a transistor, the transistor comprising a source and a drain. The method also includes depositing a metal layer on the high resistance metal etch-stop layer, where the metal layer is positioned above at least one of the source of the transistor or the drain of the transistor.

In another particular aspect, a non-transitory computer-readable medium includes data for enabling fabrication equipment to form a high resistance metal etch-stop layer for a metal layer. The data, when used by the fabrication equipment, causes the fabrication equipment to initiate deposition of the high resistance metal etch-stop layer above a metal gate of a transistor, the transistor comprising a source and a drain. The data, when used by the fabrication equipment, also causes the fabrication equipment to initiate deposition of the metal layer on the high resistance metal etch-stop layer, where the metal layer is positioned above at least one of the source of the transistor or the drain of the transistor.

In another particular aspect, an apparatus includes a transistor having a metal gate, a source, and a drain. The apparatus also includes means for providing current to at least one of the source of the transistor or the drain of the transistor. The means for providing current is positioned above at least one of the source of the transistor or the drain of the transistor. The apparatus further includes means for providing etch protection to the metal gate of the transistor. The means for providing etch protection is positioned between the metal gate of the transistor and the means for providing current.

One particular advantage provided by at least one of the disclosed aspects is an ability to form a flyover that contacts a source and/or a drain of a transistor to reduce cell size while isolating a gate of the transistor from the flyover to substantially reduce gate shortage. For example, a high resistance metal etch-stop layer (e.g., titanium nitride (TiN)) may be formed over the gate to isolate the flyover from the gate. Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram of a particular illustrative aspect of a semiconductor device having a high resistance metal etch-stop plate to form a metal flyover;

FIG. 2A illustrates a particular stage of forming the semiconductor device of FIG. 1;

FIG. 2B illustrates another particular stage of forming the semiconductor device of FIG. 1;

FIG. 2C illustrates another particular stage of forming the semiconductor device of FIG. 1;

FIG. 2D illustrates another particular stage of forming the semiconductor device of FIG. 1;

FIG. 2E illustrates another particular stage of forming the semiconductor device of FIG. 1;

FIG. 2F illustrates another particular stage of forming the semiconductor device of FIG. 1;

FIG. 2G illustrates another particular stage of forming the semiconductor device of FIG. 1;

FIG. 2H illustrates another particular stage of forming the semiconductor device of FIG. 1;

FIG. 2I illustrates another particular stage of forming the semiconductor device of FIG. 1;

FIG. 2J illustrates another particular stage of forming the semiconductor device of FIG. 1;

FIG. 3 is a diagram of another particular illustrative aspect of a semiconductor device having a high resistance metal etch-stop plate to form a metal flyover;

FIG. 4 is a diagram of another particular illustrative aspect of a semiconductor device having a high resistance metal etch-stop plate to form a metal flyover;

FIG. 5 is a diagram of another particular illustrative aspect of a semiconductor device having a high resistance metal etch-stop plate to form a metal flyover;

FIG. 6 is a diagram of a particular illustrative aspect of a semiconductor device having a high resistance metal etch-stop plate;

FIG. 7 is diagram of a particular illustrative aspect of a semiconductor device having a high resistance metal etch-stop plate that is used for a one-time programmable (OTP) memory device;

FIG. 8 is a flowchart of a particular aspect of a method for generating a metal flyover;

FIG. 9 is a block diagram of a wireless device including a semiconductor device having a high resistance metal etch-stop plate to form a metal flyover; and

FIG. 10 is a data flow diagram of a particular illustrative embodiment of a manufacturing process to manufacture electronic devices that include a semiconductor device having a high resistance metal etch-stop plate.

### V. DETAILED DESCRIPTION

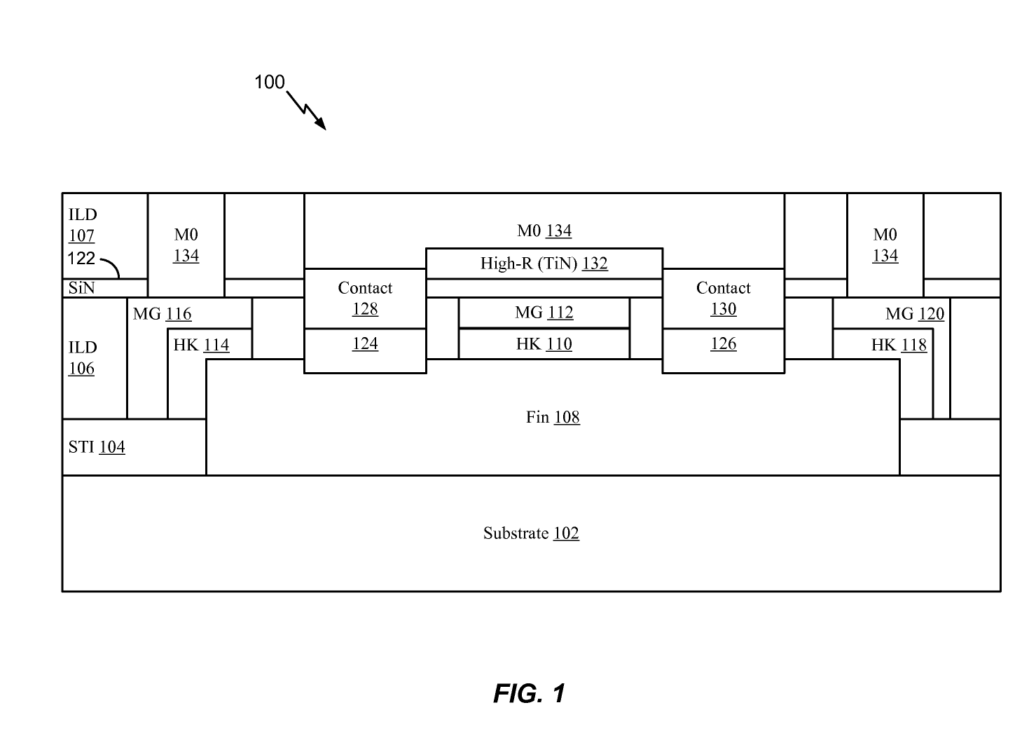

Referring to FIG. 1, a particular illustrative aspect of a semiconductor device 100 having a high resistance metal etch-stop plate to enable a metal flyover is shown. The semiconductor device 100 includes a substrate 102, a shallow trench isolation (STI) layer 104, and an inter-layer dielectric (ILD) 106. In a particular aspect, the substrate 102 may be a p-type substrate. In another particular aspect, the substrate 102 may be an n-type substrate. The semiconductor device 100 also includes a fin 108 (e.g., a source-channel-drain region) etched from the substrate 102.

A first high constant (HK) material 110 may be formed on the fin 108, and a first metal gate (MG) 112 may be formed on top of the first HK material 110. A second HK material 114 may also be formed on the fin 108, and a second metal gate 116 may be formed on the second HK material 114. A third HK material 118 may also be formed on the fin 108, and a third metal gate 120 may be formed on the third HK material 118. In a particular aspect, the first metal gate 112 may be a metal gate of a first transistor, the second metal gate 116 may be a dummy metal gate, and the third metal gate 120 may be a dummy metal gate. A silicon nitride (SiN) layer 122 (e.g., a capping layer) may be formed on top of the ILD 106.

The fin 108 may include a first source/drain region 124 and a second source/drain region 126. For ease of illustration, the first source/drain region 124 will be described as a “source” of the fin 108, and the second source/drain region 126 will be described as a “drain” of the fin 108. However, in other particular aspects, the first source/drain region 124 may be a drain, and the second source/drain region 126 may be a source. A first contact 128 (e.g., a metal “conducting” material) may be coupled to the source 124 of the fin 108. In a similar manner, a second contact 130 (e.g., a metal “conducting” material) may be coupled to the drain 126 of the fin 108.

A high resistance metal etch-stop layer 132 (e.g., a high resistive plate) may be formed on top of the SiN layer 122 to function as an etch-stop layer. For example, as illustrated in FIG. 1, the high resistance metal etch-stop layer 132 may be positioned above the first metal gate 112 (e.g., the metal gate of the first transistor). In a particular aspect, the high resistance metal etch-stop layer 132 may be comprised of titanium nitride (TiN).

A metal layer 134 (e.g., an “MO” layer) may be formed on the high resistance metal etch-stop layer 132. The metal layer 134 may be a “flyover”. For example, the metal layer 134 may also be positioned above the source 124 of the first transistor and above the drain 126 of the first transistor as to “flyover” the first metal gate 112. The metal layer 134 may be electrically coupled to the source 124 via the first contact 128, and the metal layer 134 may be electrically coupled to the drain 126 via the second contact 130. Thus, the metal layer 134 may operate at an inter-device contact that couples the source 124 and/or the drain 126 to one or more other circuit components (e.g., another transistor, a resistor, an inductor, a capacitor, etc.).

The metal layer 134 may also be electrically coupled to the second metal gate 116. For example, the metal layer 134 may be formed (e.g., deposited) through the SiN layer 122 and coupled to the second metal gate 116. Thus, the metal layer 134 may function as an inter-device contact that couples the second metal gate 116 to one or more other circuit components (e.g., another transistor, a resistor, an inductor, a capacitor, etc.). In a similar manner, the metal layer 134 may be electrically coupled to the third metal gate 120. For example, the metal layer 134 may be formed through the SiN layer 122 and coupled to the third metal gate 120. Thus, the metal layer 134 may function as an inter-device contact that couples the third metal gate 120 to one or more other circuit components.

The high resistance metal etch-stop layer 132 may isolate the metal layer 134 (e.g., the flyover) from the first metal gate 112 by preserving an isolation margin (e.g., between approximately 20 nanometers to 35 nanometers) based on a thickness of the SiN layer 122 (or other isolating layers). For example, the high resistance metal etch-stop layer 132 may prevent the metal layer 134 from contacting, or coming within a relatively close proximity of, the first metal gate 112 (e.g., prevent the metal layer 134 from etching through the SiN layer 122). As a result, the high resistance metal etch-stop layer 132 may substantially prohibit the metal layer 134 from providing an electrical short to the first metal gate 112. For example, the high resistance metal etch-stop layer 132 may electrically isolate the first metal gate 112 from the metal layer 134. Isolating the first metal gate 112 from the metal layer 134 may enable bias control of the first metal gate 112. For example, voltages applied to the source 124 and/or to the drain 126 via the metal layer 134 may be isolated from (e.g., prevented from shorting) the first metal gate 112. As a result, an independent voltage may be applied to the first metal gate 112 at a location away from the metal layer 134 (e.g., a location into or out of the page) to bias the first metal gate 112.

The semiconductor device 100 of FIG. 1 may provide electrical isolation between the first metal gate 112 and the metal layer 134 via the high resistance metal etch-stop layer 132. The electrical isolation may reduce the likelihood of the metal layer 134 shorting the first metal gate 112 and may enable an independent contact (not shown) to bias the first metal gate 112. For example, the independent contact may be coupled to the first metal gate 112 at a location out of the proximity of the metal layer 134 (e.g., at a location into the page or at a location out of the page).

FIG. 1 is a cross-sectional view of the semiconductor device 100 that corresponds to an area that includes the fin 108. A cross-sectional view at another portion of the semiconductor device 100 may not include the fin 108.

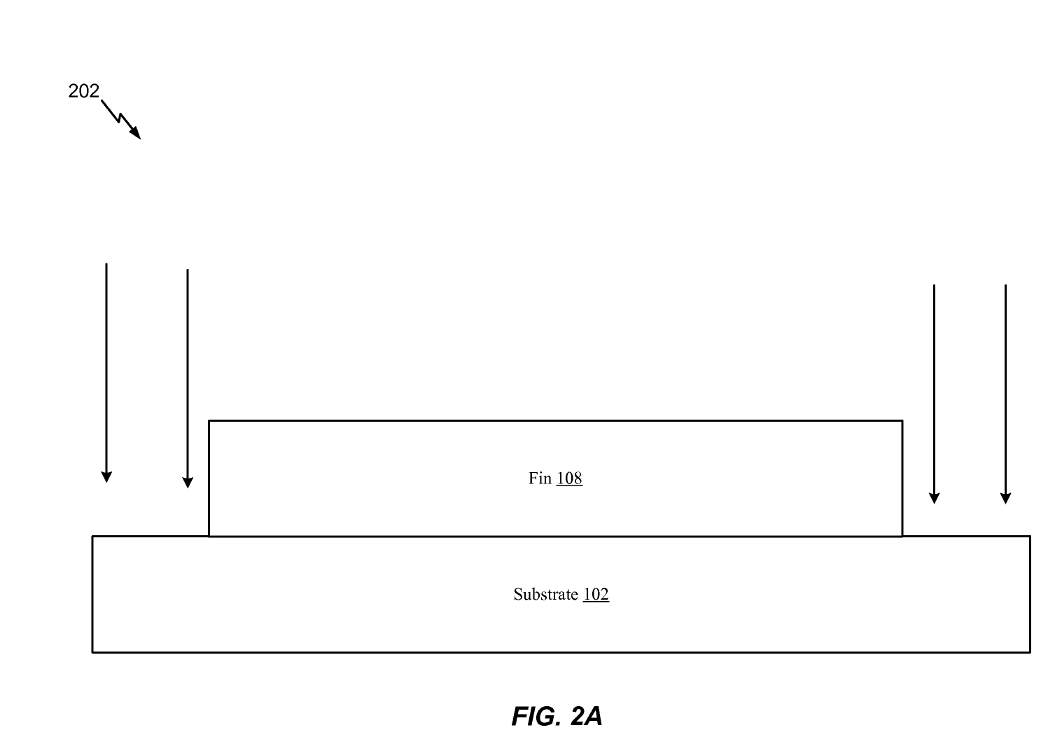

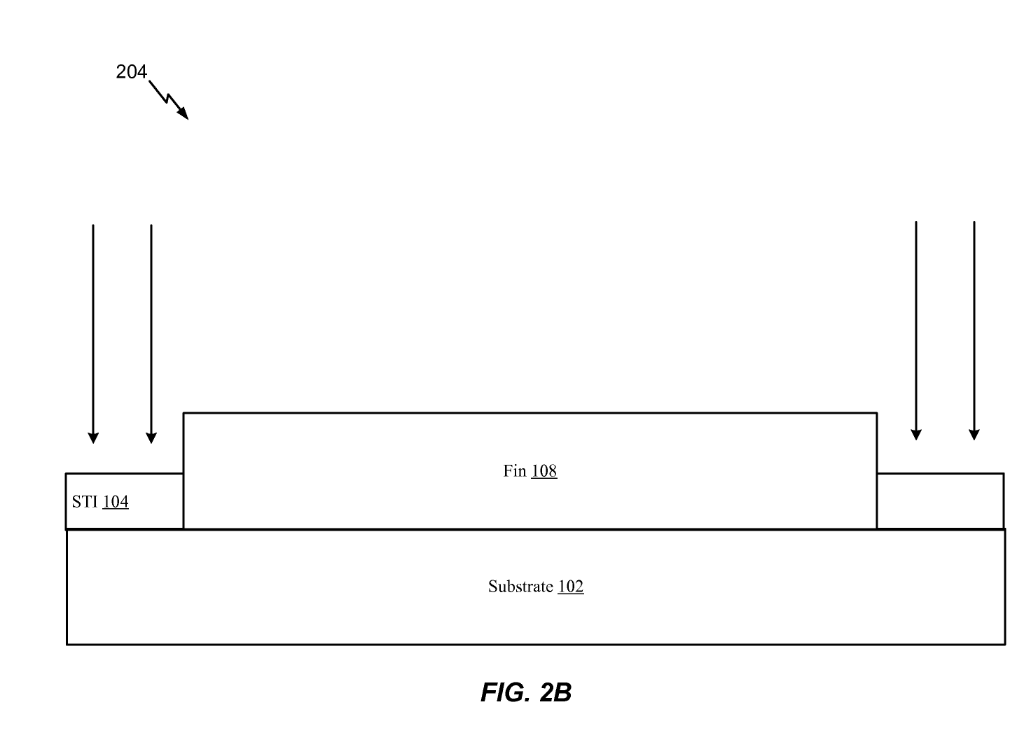

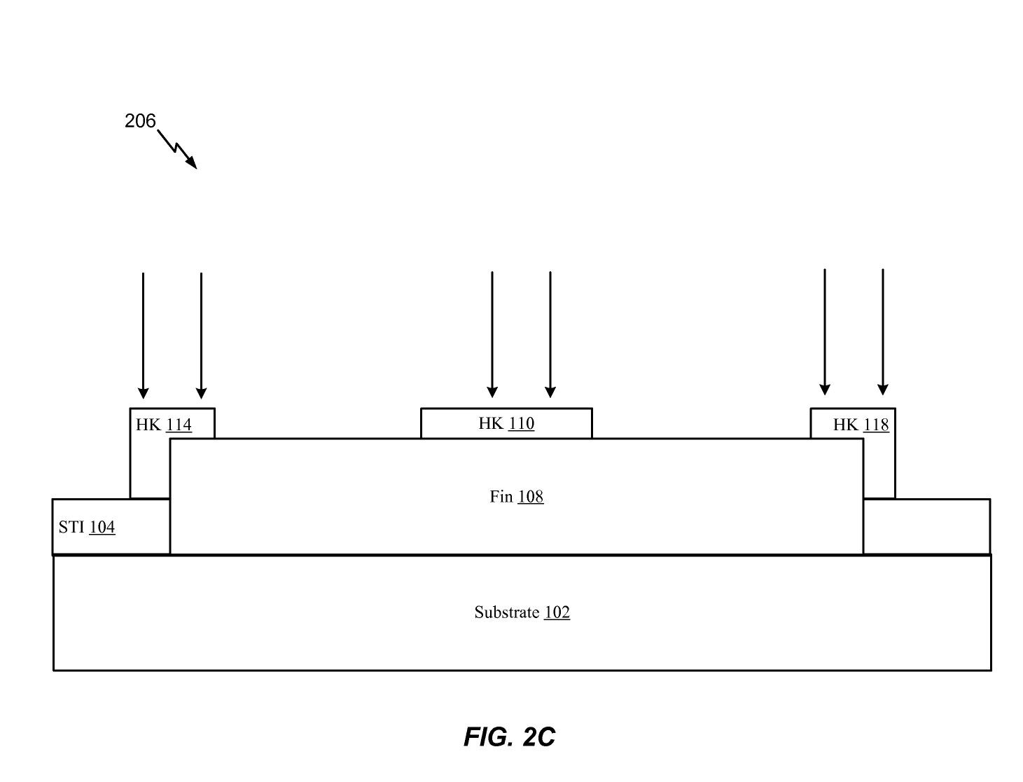

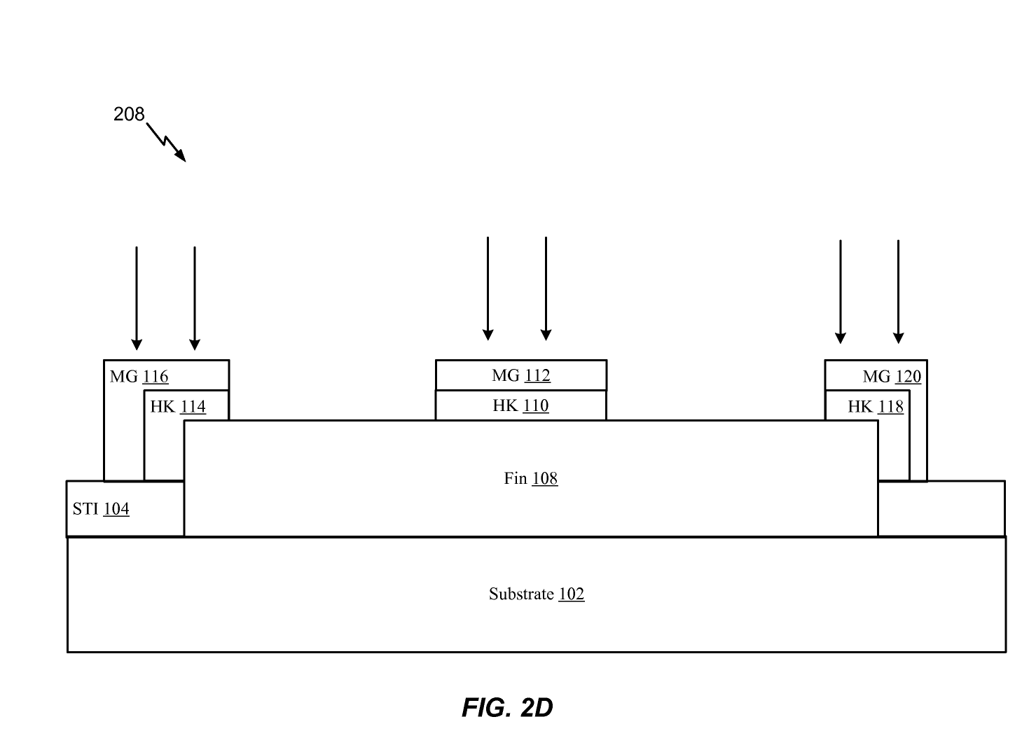

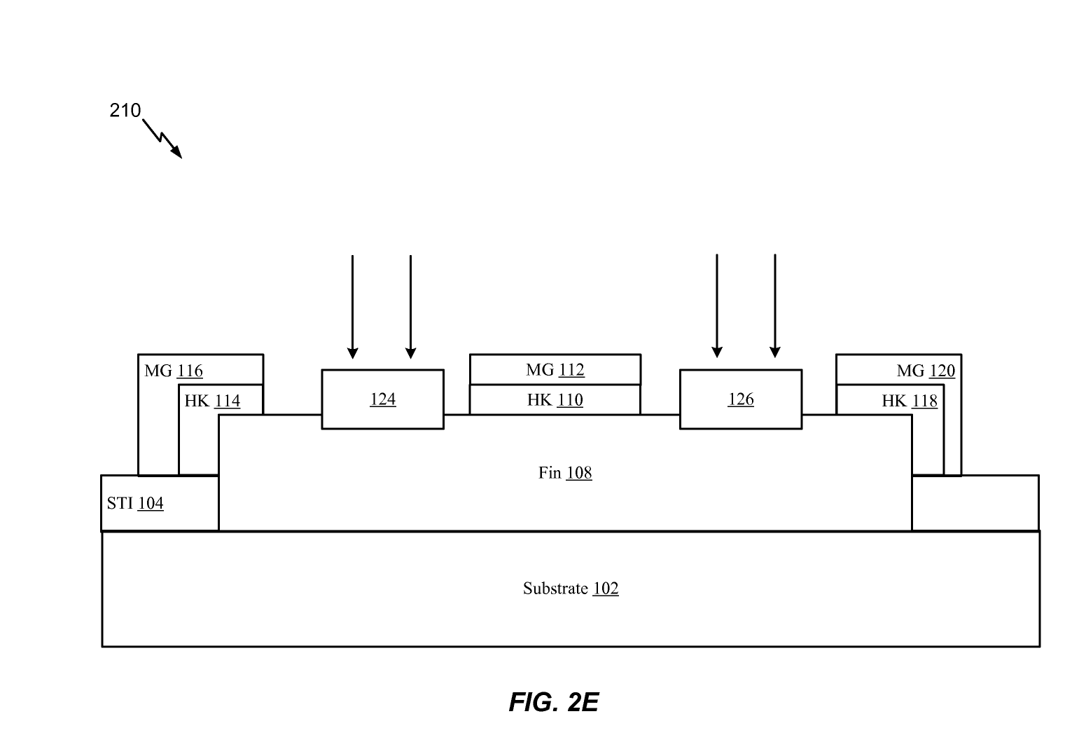

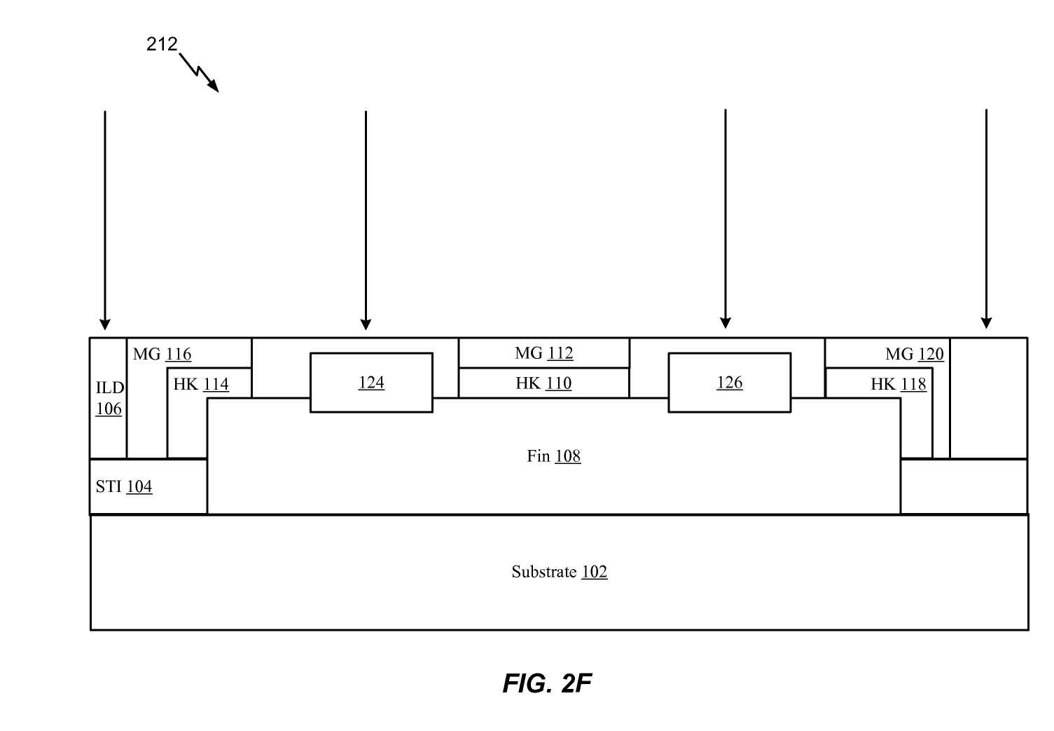

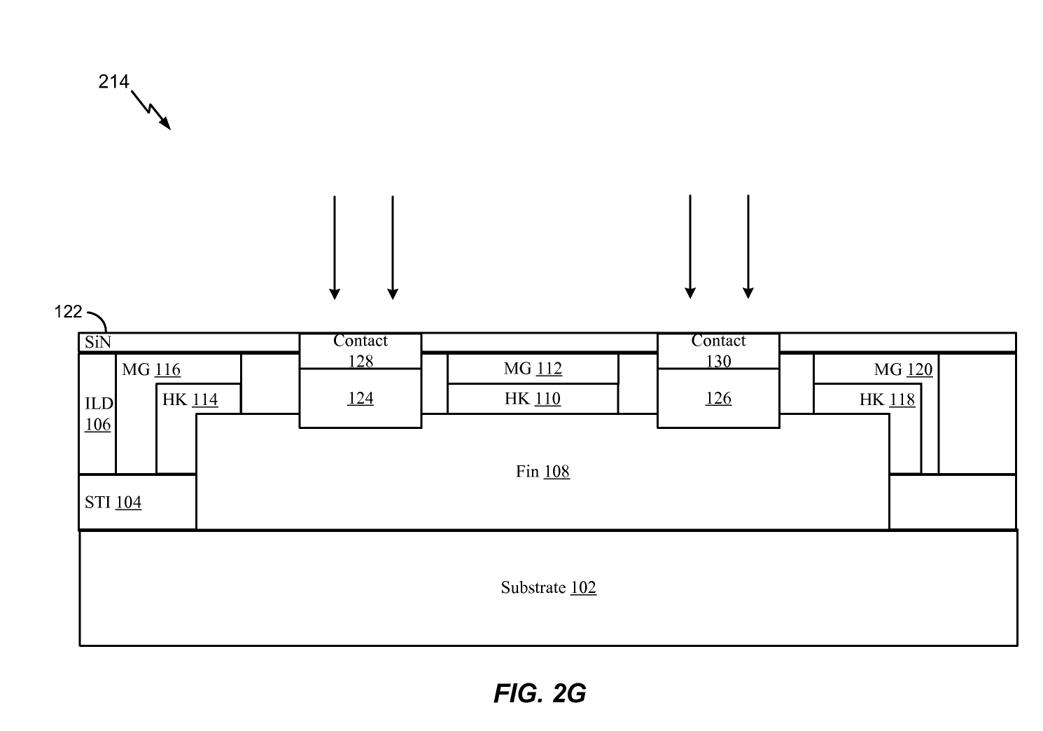

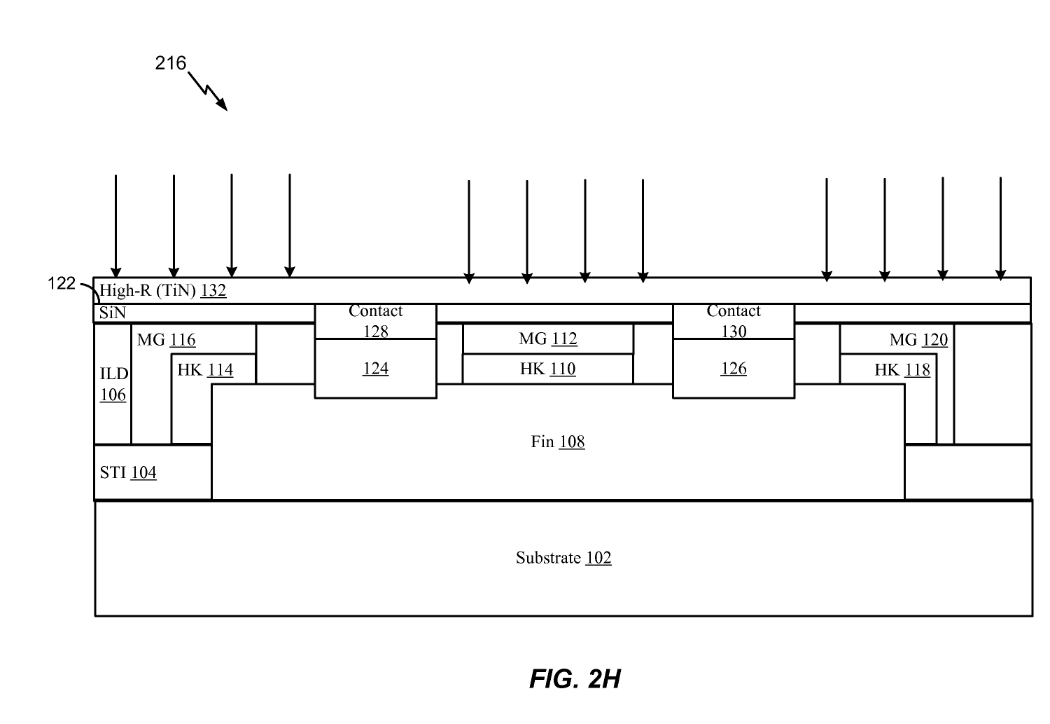

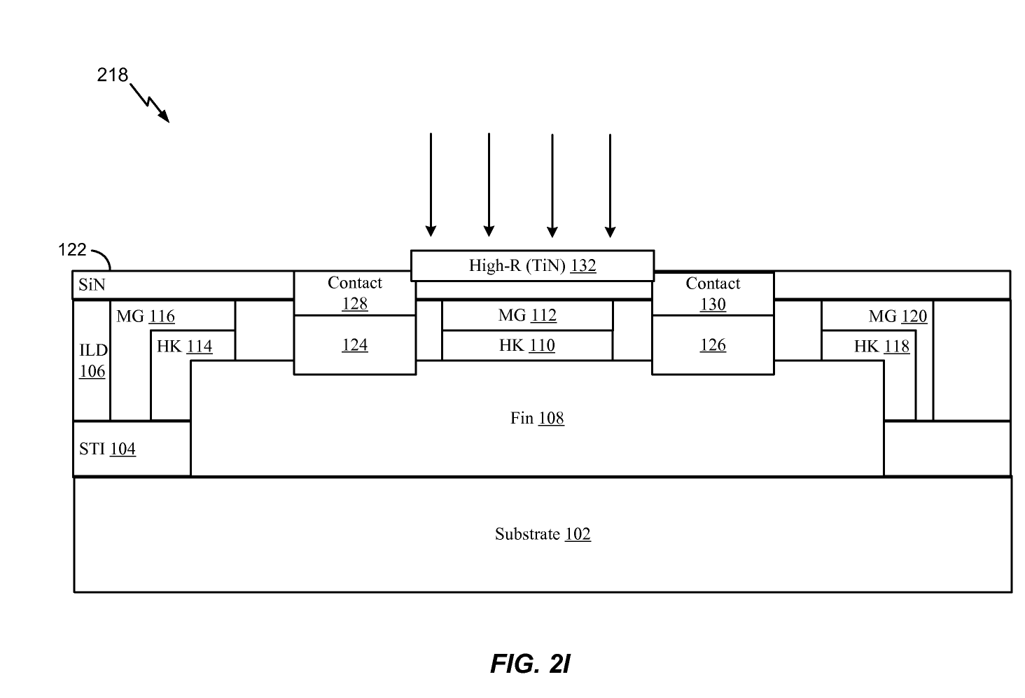

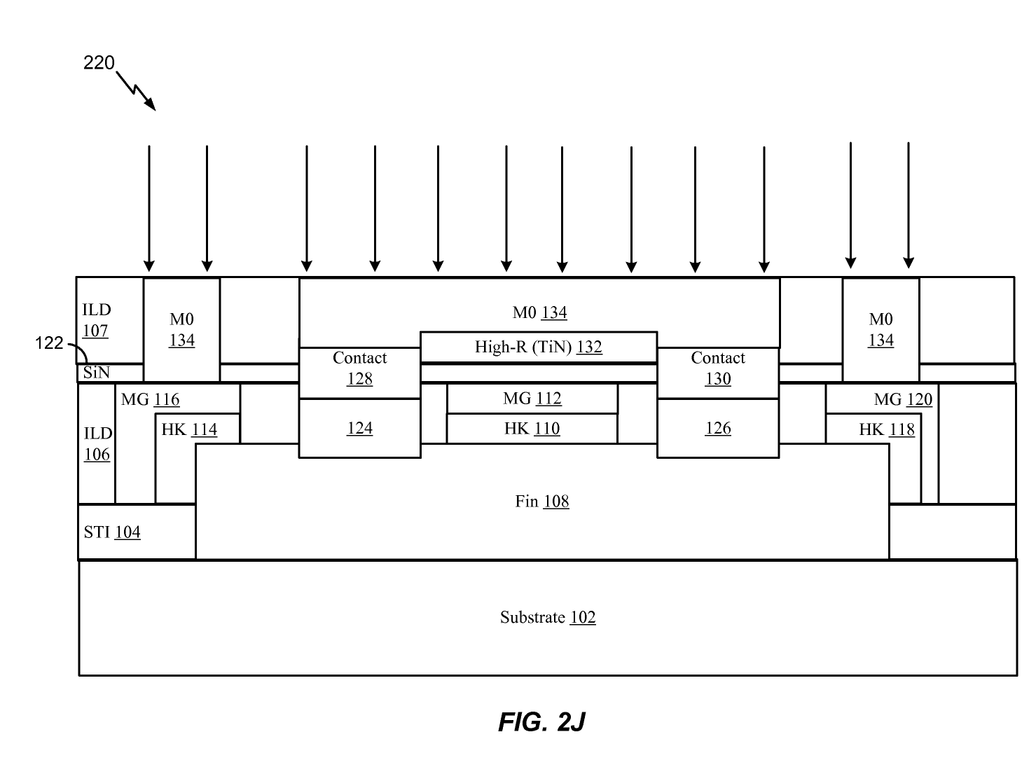

Referring to FIG. 2A, a particular stage 202 of forming the semiconductor device 100 of FIG. 1 is shown. According to the stage 202 of FIG. 2A, the substrate 102 may undergo an etching process to form the fin 108. For example, a hard mask (not shown) may be placed on a particular area on top of the substrate 102 to protect the particular area during an etching process (e.g., a reactive ion etching process). The substrate 102 may undergo the reactive ion etching process to generate the fin 108. The hard mask may be removed using a planarization process and wet etch process (e.g., a dry plasma etching process or a chemical mechanical planarization (CMP) process or wet chemical etch process). For n-type metal oxide semiconductor (NMOS) formation, the substrate 102 and the fin 108 may be comprised of a p-type material. For p-type metal oxide semiconductor (PMOS) formation, the substrate 102 and the fin 108 may be comprised of an n-type material.

Referring to FIG. 2B, another particular stage 204 of forming the semiconductor device 100 of FIG. 1 is shown. According to the stage 204 of FIG. 2B, the shallow trench isolation layer 104 may be deposited into trenches adjacent to the fin 108. In a particular aspect, the shallow trench isolation layer 104 may be deposited into the trenches prior to removing the hard mask placed on the particular area on top of the substrate 102, and the hard mask may be removed using the planarization process and wet etch process after the trenches have been filled with the shallow trench isolation layer 104. The shallow trench isolation layer 104 may be comprised of a dielectric material, such as silicon dioxide.

Referring to FIG. 2C, another particular stage 206 of forming the semiconductor device 100 of FIG. 1 is shown. According to the stage 206 of FIG. 2C, the first HK material 110, the second HK material 114, and the third HK material 118 may be deposited on the fin 108. The HK materials 110, 114, 118 may be deposited using atomic layer deposition and patterning process. In a particular aspect, the HK materials 110, 114, 118 may be comprised of hafnium silicate, zirconium silicate, hafnium oxide, or zirconium dioxide.

Referring to FIG. 2D, another particular stage 208 of forming the semiconductor device 100 of FIG. 1 is shown. According to the stage 208 of FIG. 2D, the first metal gate 112 may be formed (e.g., deposited) on the first HK material 110, the second metal gate 116 may be formed on the second HK material 114, and the third metal gate 120 may be formed on the third HK material 118. In a particular aspect, the first metal gate 112 may be the metal gate of the first transistor, the second metal gate 116 may be the dummy metal gate, and the third metal gate 120 may be the dummy metal gate.

Referring to FIG. 2E, another particular stage 210 of forming the semiconductor device 100 of FIG. 1 is shown. According to the stage 210 of FIG. 2E, the source 124 of the fin 108 may be deposited onto the fin 108, and the drain 126 of the fin 108 may be deposited onto the fin 108. For NMOS formation, the source 124 and the drain 126 may be comprised of an n-type material. For PMOS formation, the source 124 and the drain 126 may be comprised of a p-type material.

Referring to FIG. 2F, another particular stage 212 of forming the semiconductor device 100 of FIG. 1 is shown. According to the stage 212 of FIG. 2F, the ILD 106 may be deposited into exposed trenches. For example, a hard mask may be placed on the first metal gate 112, the second metal gate 116, and the third metal gate 120. The ILD 106 may be deposited into the trenches and the hard mask may be removed from the metal gates 112, 116, 120 using a planarization process after the ILD 106 is deposited.

Referring to FIG. 2G, another particular stage 214 of forming the semiconductor device 100 of FIG. 1 is shown. According to the stage 214 of FIG. 2G, the SiN layer 122 may be deposited on top of the ILD 106, the first contact 128 may be formed on the source 124, and the second contact 130 may be formed on the drain 126. For example, the contacts 128, 130 may be deposited through the SiN cap 122 and the ILD 106 to electrically couple to the source 124 and to the drain 126, respectively.

Referring to FIG. 2H, another particular stage 216 of forming the semiconductor device 100 of FIG. 1 is shown. According to the stage 216 of FIG. 2H, the high-R (TiN) layer 132 may be deposited on top of the SiN cap 122 and the ILD 106. For example, the high-R (TiN) layer 132 may be deposited onto the SiN cap 122.

Referring to FIG. 2I, another particular stage 218 of forming the semiconductor device 100 of FIG. 1 is shown. According to the stage 218 of FIG. 2I, the high resistance metal etch-stop layer 132 may be patterned on the SiN layer 122 above the first metal gate 112. For example, the high resistance metal etch-stop layer 132 may be function as an etch-stop to prevent the metal layer 134 from extending through the SiN layer 122 and contacting the first metal gate 112.

Referring to FIG. 2J, another particular stage 220 of forming the semiconductor device 100 of FIG. 1 is shown. According to the stage 220 of FIG. 2J, an ILD 107 may be deposited on top of the SiN layer 122, the first contact 128, the second contact 130, and the high resistance metal etch-stop layer 132. After deposition of the ILD 107, the metal layer 134 may be formed at select locations according to a mask design by a damascene trench process in the ILD 107. For example, a damascene trench mask having patterning above the first contact 128, the high resistance metal etch-stop layer 132, the second contact 130, the second metal gate 116, and the third metal gate 120 may be placed on the structure. The metal layer 134 may be deposited into the openings of the damascene trench such that the metal layer 134 is deposited through the SiN layer 122 to contact (e.g., electrically couple to) the second metal gate 116 and the third metal gate 120. The metal layer 134 may be deposited onto the first contact 128 and the second contact 130 such that the metal layer 134 is electrically coupled to the source 124 and to the drain 126, respectively.

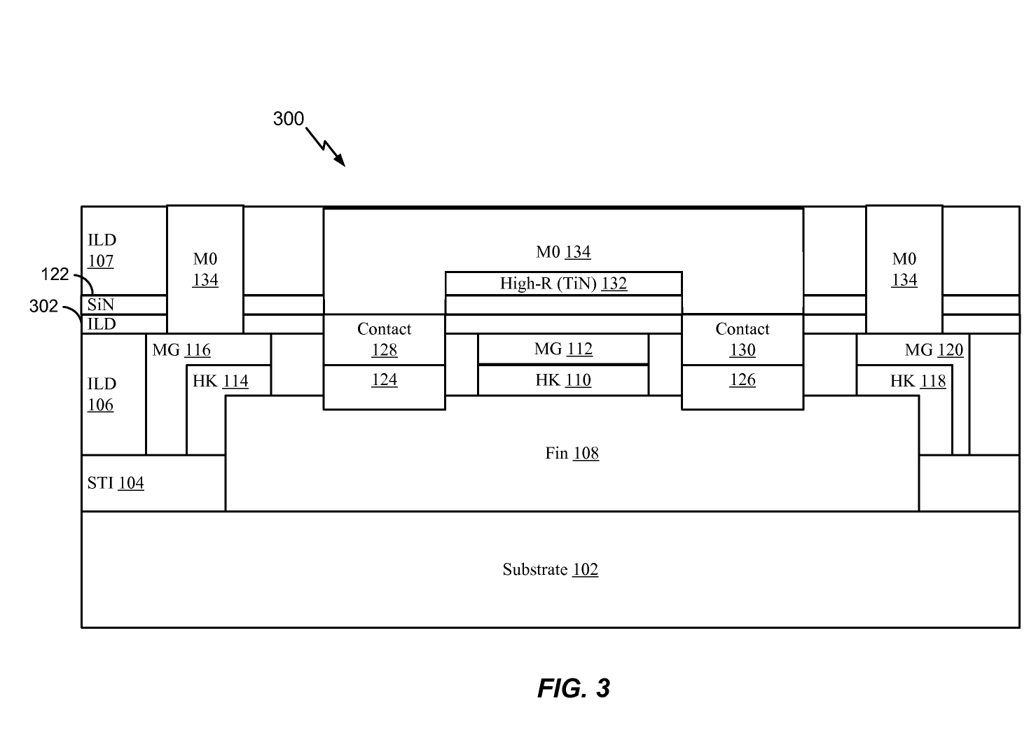

The metal layer 134 may also be deposited onto the high resistance metal etch-stop layer 132 as a flyover (e.g., the metal layer 134 “flies over” the first metal gate 112). The high resistance metal etch-stop layer 132 may isolate the metal layer 134 from the first metal gate 112 by preserving an isolation margin (e.g., between approximately 20 nanometers to 35 nanometers) based on a thickness of the SiN layer 122 (and/or other isolating layers, as described with respect to FIG. 3). For example, the high resistance metal etch-stop layer 132 may prevent the metal layer 134 from contacting, or coming within a relatively close proximity of, the first metal gate 112 (e.g., prevent the metal layer 134 from etching through the SiN layer 122). As a result, the high resistance metal etch-stop layer 132 may substantially prohibit the metal layer 134 from providing an electrical short to the first metal gate 112. For example, the high resistance metal etch-stop layer 132 may electrically isolate the first metal gate 112 from the metal layer 134 to enable bias control of the first metal gate 112.

Referring to FIG. 3, another particular illustrative aspect of a semiconductor device 300 having a high resistance metal etch-stop plate to enable a metal flyover is shown. The semiconductor device 300 may include the layers and components of the semiconductor device 100 of FIG. 1.

Additionally, the semiconductor device 300 may include a second ILD 302. For example, the second ILD 302 may be deposited on top of the ILD 106 and the metal gates 112, 116, 120. For example, after stage 212 of FIG. 2F, the second ILD 302 may be deposited on top of the ILD 106 and the metal gates 112, 116, 120. The contacts 128, 130 may be formed through the second ILD 302 and the ILD 106 to electrically couple to the source 124 and to the drain 126, respectively.

The second ILD 302 may provide extra isolation between the metal layer 134 and the first metal gate 112. For example, the high resistance metal etch-stop layer 132 may isolate the metal layer 134 from the first metal gate 112 by preserving an isolation margin based on a thickness of the SiN layer 122 and based on a thickness of the second ILD 302. For example, the high resistance metal etch-stop layer 132 may prevent the metal layer 134 from contacting, or coming within a relatively close proximity of, the first metal gate 112 (e.g., prevent the metal layer 134 from etching through the SiN layer 122). As a result, the high resistance metal etch-stop layer 132 may substantially prohibit the metal layer 134 from providing an electrical short to the first metal gate 112.

FIG. 3 is a cross-sectional view of the semiconductor device 300 that corresponds to an area that includes the fin 108. A cross-sectional view at another portion of the semiconductor device 300 may not include the fin 108.

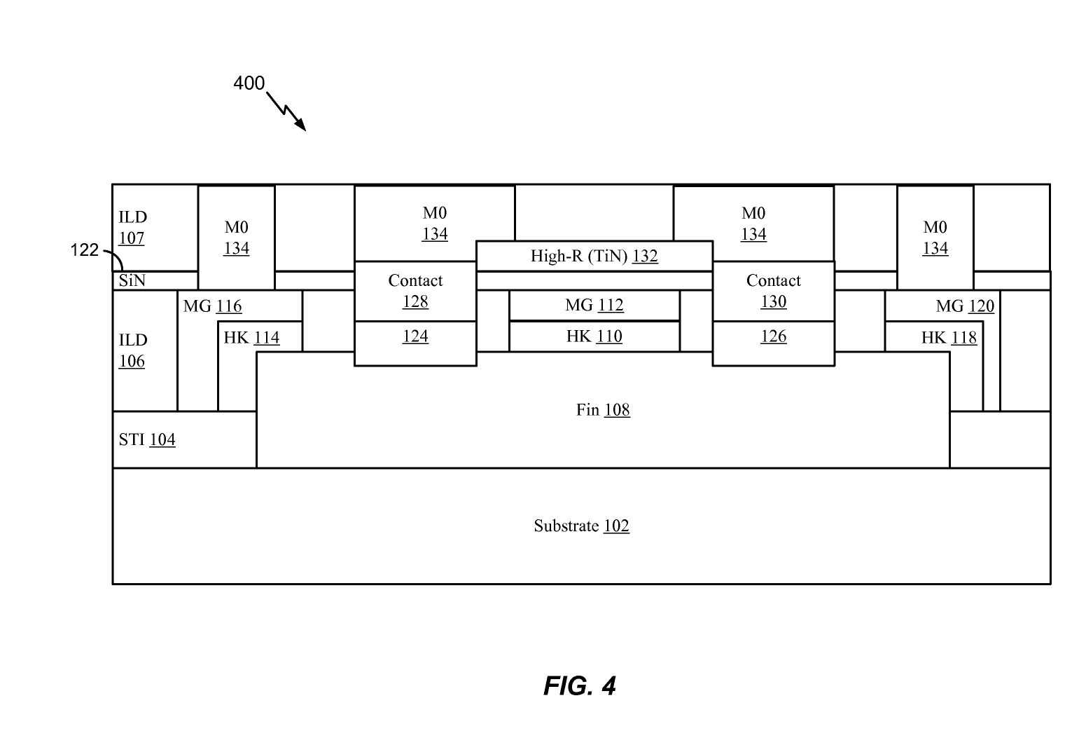

Referring to FIG. 4, another particular illustrative aspect of a semiconductor device 400 having a high resistance metal etch-stop plate to enable a metal flyover is shown. The semiconductor device 400 may include the layers and components of the semiconductor device 100 of FIG. 1.

However, in FIG. 4, the metal layer 134 may be positioned above a portion of the high resistance metal etch-stop layer 132 as opposed to positioned above the entire high resistance metal etch-stop layer 132. For example, with reference to FIG. 2J, the damascene trench mask may have “openings” above the first contact 128, a portion of the high resistance metal etch-stop layer 132, the second contact 130, the second metal gate 116, and the third metal gate 120 and the damascene trench mask may be placed on the structure. The metal layer 134 may be deposited into the openings of the damascene trench such that the metal layer 134 is deposited through the SiN layer 122 to contact (e.g., electrically couple to) the second metal gate 116 and the third metal gate 120. The metal layer 134 may be deposited onto the first contact 128 and the second contact 130 such that the metal layer 134 is electrically coupled to the source 124 and to the drain 126, respectively. The metal layer 134 may also be deposited onto portions of the high resistance metal etch-stop layer 132 as a flyover, as shown in FIG. 4. The semiconductor device 400 of FIG. 4 may enable the high resistance metal etch-stop layer 132 to function as a local interconnect (e.g., function as a conductive path between different layers or components of the semiconductor device 400).

FIG. 4 is a cross-sectional view of the semiconductor device 400 that corresponds to an area that includes the fin 108. A cross-sectional view at another portion of the semiconductor device 400 may not include the fin 108.

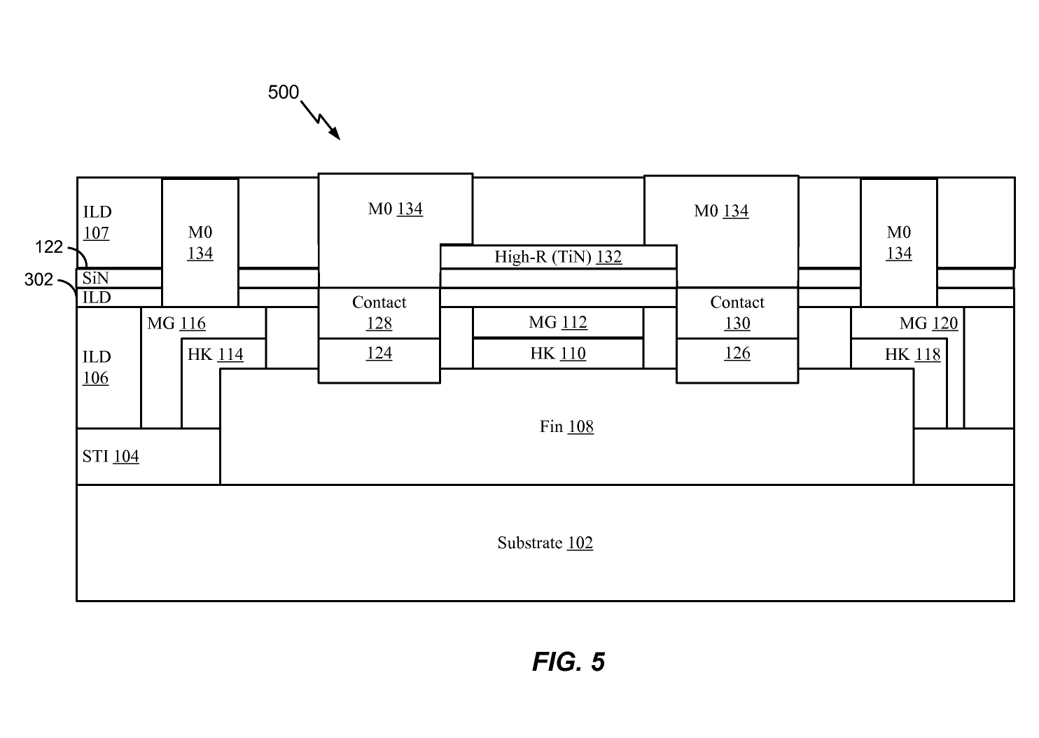

Referring to FIG. 5, another particular illustrative aspect of a semiconductor device 500 having a high resistance metal etch-stop plate to enable a metal flyover is shown. The semiconductor device 500 may include the layers and components of the semiconductor device 100 of FIG. 3.

However, in FIG. 5, the metal layer 134 may be positioned above a portion of the high resistance metal etch-stop layer 132 as opposed to positioned above the entire high resistance metal etch-stop layer 132. For example, with reference to FIG. 2J, the damascene trench mask may have “openings” above the first contact 128, a portion of the high resistance metal etch-stop layer 132, the second contact 130, the second metal gate 116, and the third metal gate 120 may be placed on the structure. The metal layer 134 may be deposited into the openings of the damascene trench such that the metal layer 134 is deposited through the SiN layer 122 to contact (e.g., electrically couple to) the second metal gate 116 and the third metal gate 120. The metal layer 134 may be deposited onto the first contact 128 and the second contact 130 such that the metal layer 134 is electrically coupled to the source 124 and to the drain 126, respectively. The metal layer 134 may also be deposited onto portions of the high resistance metal etch-stop layer 132 as a flyover, as shown in FIG. 5. The semiconductor device 500 of FIG. 5 may enable the high resistance metal etch-stop layer 132 to function as a local interconnect.

FIG. 5 is a cross-sectional view of the semiconductor device 500 that corresponds to an area that includes the fin 108. A cross-sectional view at another portion of the semiconductor device 500 may not include the fin 108.

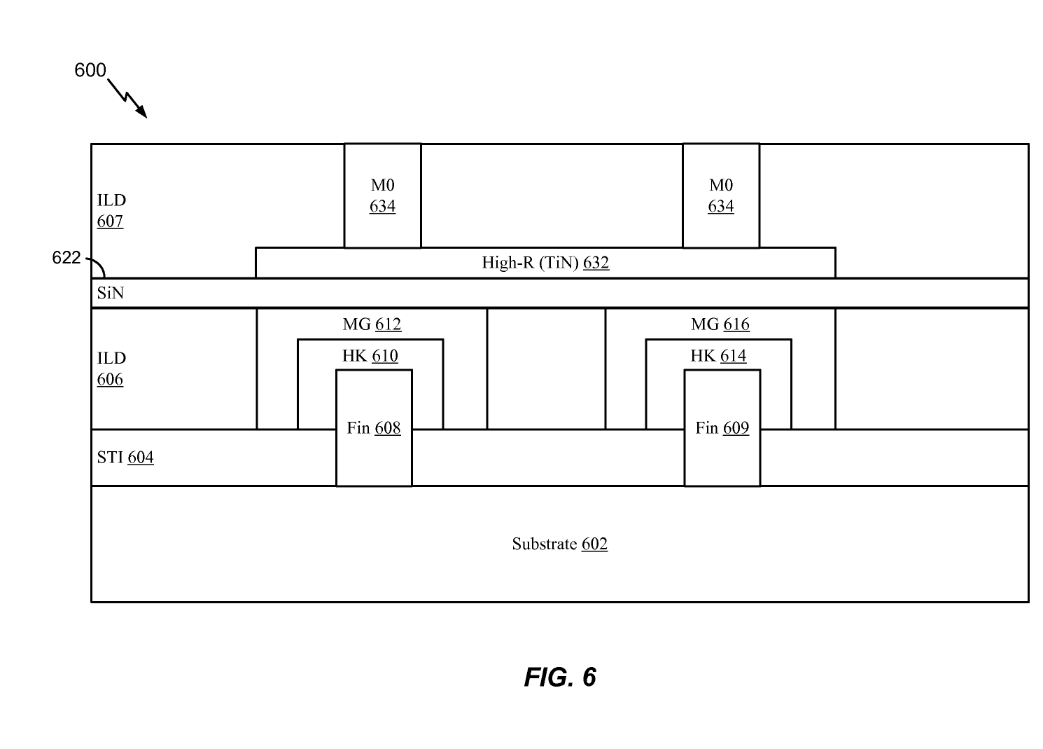

Referring to FIG. 6, a particular illustrative aspect of a semiconductor device 600 having a high resistance metal etch-stop plate is shown. The semiconductor device 600 includes a substrate 602, a STI 604, and an ILD 606 and 607. In a particular aspect, the substrate 602 may be a p-type substrate. In another particular aspect, the substrate 602 may be an n-type substrate.

The semiconductor device 600 also includes a first fin 608 and a second fin 609 that are etched from the substrate 602 using a reactive ion etching process. A first HK material 610 may be formed on the first fin 608, and a second HK material 614 may be formed on the second fin 609. A first metal gate 612 may be formed on the first HK material 610, and a second metal gate 616 may be formed on the second HK material 614. In a particular aspect, a first transistor may be comprised of the first fin 608, the first HK material 610, and the first metal gate 612. Additionally, a second transistor may be comprised of the second fin 609, the second HK material 614, and the second metal gate 616.

A SiN layer 622 may be formed on the metal gates 612, 616 and on the ILD 606. A high resistance metal etch-stop layer 632 (e.g., a high resistive plate) may be positioned above the metal gates 612, 616 and formed on the SiN layer 622. In a particular aspect, the high resistance metal etch-stop layer 632 may be comprised of titanium nitride (TiN).

A metal layer 634 (e.g., an “MO” layer) may be formed on the high resistance metal etch-stop layer 632. The high resistance metal etch-stop layer 632 may be positioned above the first metal gate 612 and above the second metal gate 616. The high resistance metal etch-stop layer 632 may isolate the metal layer 634 from the first metal gate 612 and from the second metal gate 616. For example, the high resistance metal etch-stop layer 632 may prevent the metal layer 634 from contacting, or coming within a relatively close proximity of, the metal gates 612, 616. As a result, the high resistance metal etch-stop layer 632 may substantially prohibit the metal layer 634 from providing an electrical short to the metal gates 612, 616.

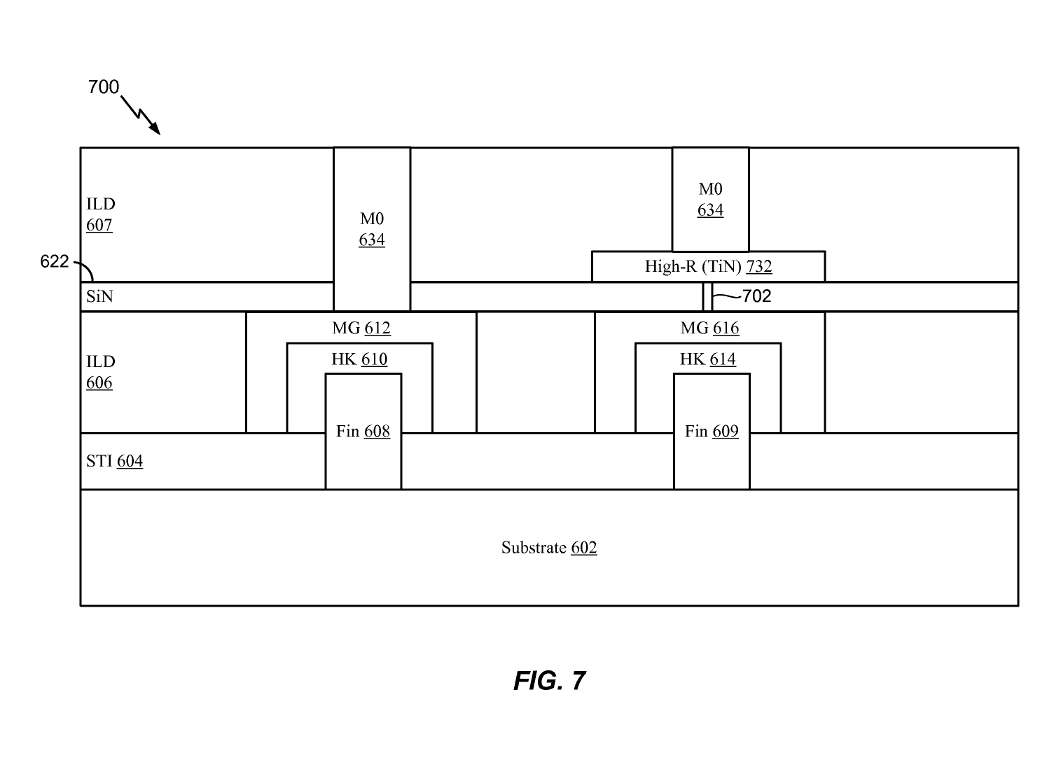

Referring to FIG. 7, a particular illustrative aspect of a semiconductor device 700 having a high resistance metal etch-stop plate that is used for a one-time programmable (OTP) memory device is shown. The semiconductor device 700 may include layers and components of the semiconductor device 600 of FIG. 6.

However, in FIG. 7, the first metal gate 612 may not be protected by a high resistance metal etch-stop layer. Thus, the metal layer 634 may etch through the SiN layer 622 and contact (e.g., short) the first metal gate 612. A high resistance metal etch-stop layer 732 may be positioned on the SiN layer 622 above the second metal gate 616. In a particular aspect, the high resistance metal etch-stop layer 732 may be comprised of titanium nitride (TiN). The high resistance metal etch-stop layer 732 may isolate the metal layer 634 from the second metal gate 616. For example, the high resistance metal etch-stop layer 732 may prevent the metal layer 634 from contacting, or coming within a relatively close proximity of, the second metal gate 616. As a result, the high resistance metal etch-stop layer 732 may substantially prohibit the metal layer 634 from providing an electrical short to the second metal gate 616.

A relatively large voltage may be provided to the metal layer 634 such that a breakdown condition occurs between the high resistance metal etch-stop layer 732 and the second metal gate 616. A conductive path 702 may be formed through the SiN layer 622 due to the breakdown condition. The breakdown condition may correspond to a logical value that is programmed (and read) at an OTP device. For example, in a particular aspect, the creation of the breakdown condition may correspond to the OTP device storing a logical “1” value as opposed to a logical “0” value. In an alternative aspect, the creation of the breakdown condition may correspond to the OTP device storing a logical “0” value as opposed to a logical “1” value.

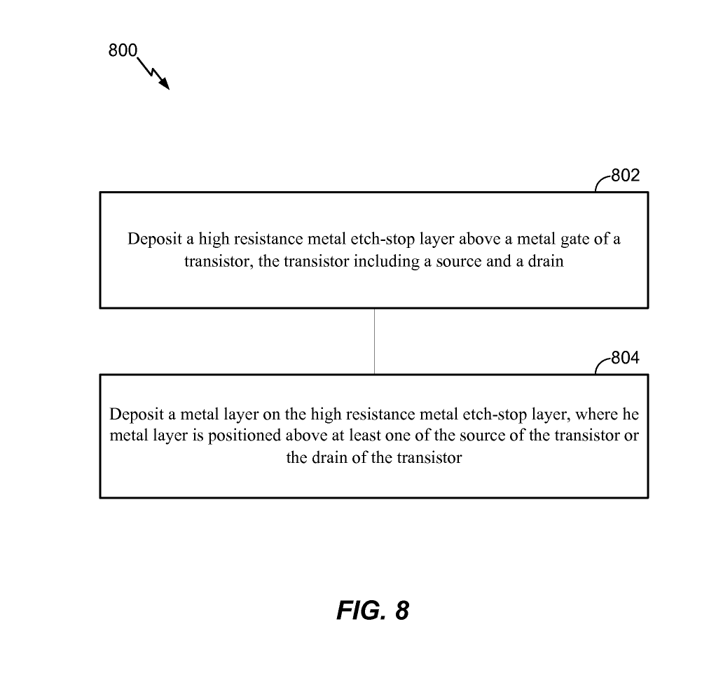

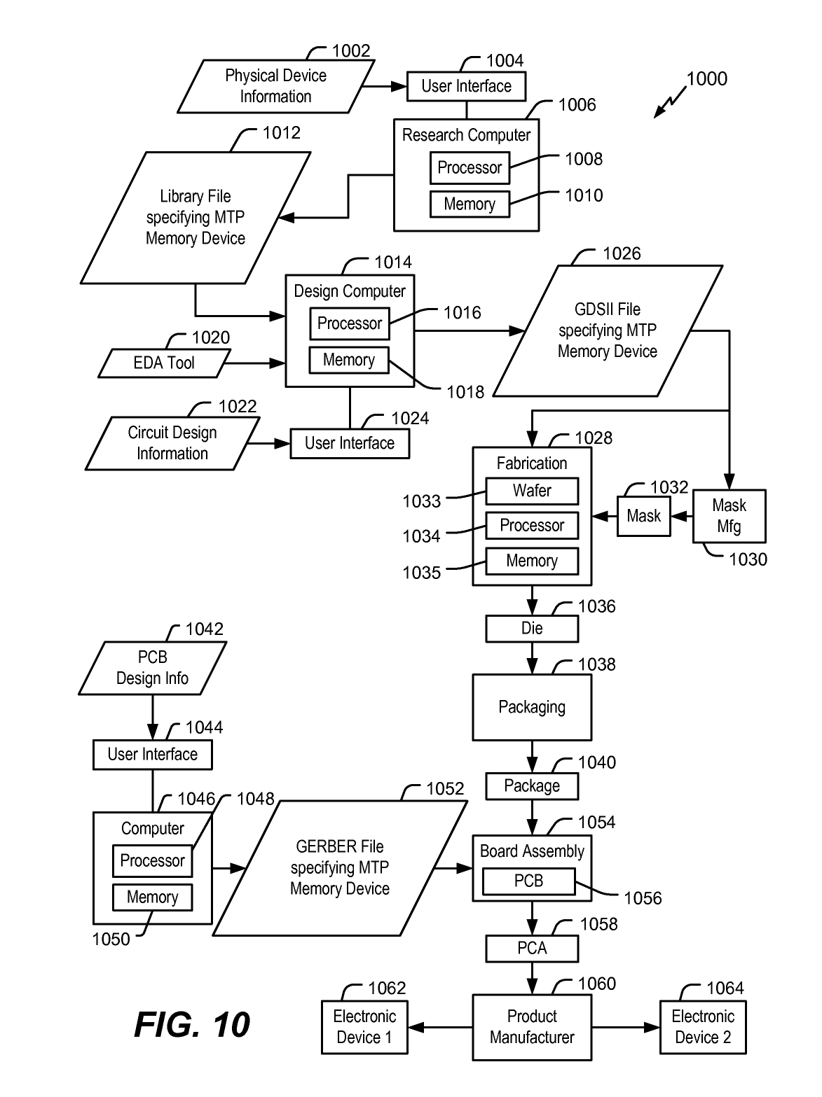

Referring to FIG. 8, a flowchart that illustrates a method 800 of generating a metal flyover is shown. The method 800 may be performed using manufacturing equipment described with respect to FIG. 10.

The method 800 includes depositing a high resistance metal etch-stop layer above a metal gate of a transistor, at 802. For example, referring to FIG. 2I, the high resistance metal etch-stop layer 132 may be deposited on the SiN layer 122 above the first metal gate 112. The transistor may include a source (e.g., the source 124 of FIG. 1) and a drain (e.g., the drain 126 of FIG. 1).

A metal layer may be deposited on the high resistance metal etch-stop layer, at 804. For example, referring to FIG. 2J, the metal layer 134 may be deposited onto the high resistance metal etch-stop layer 132. The high resistance metal etch-stop layer 132 may isolate the metal layer 134 from the first metal gate 112 by preserving an isolation margin (e.g., between approximately 20 nanometers to 35 nanometers) based on a thickness of the SiN layer 122. For example, the high resistance metal etch-stop layer 132 may prevent the metal layer 134 from contacting, or coming within a relatively close proximity of, the first metal gate 112 (e.g., prevent the metal layer 134 from etching through the SiN layer 122). As a result, the high resistance metal etch-stop layer 132 may substantially prohibit the metal layer 134 from providing an electrical short to the first metal gate 112.

The method 800 of FIG. 8 may be used to form any of the semiconductor devices depicted in FIGS. 1 and 3-7. Further, one or more of the stages of forming a semiconductor device (as illustrated in FIGS. 2A-2J) may be implemented in conjunction with the method 800 to form any of the semiconductor devices depicted in FIGS. 1 and 3-7.

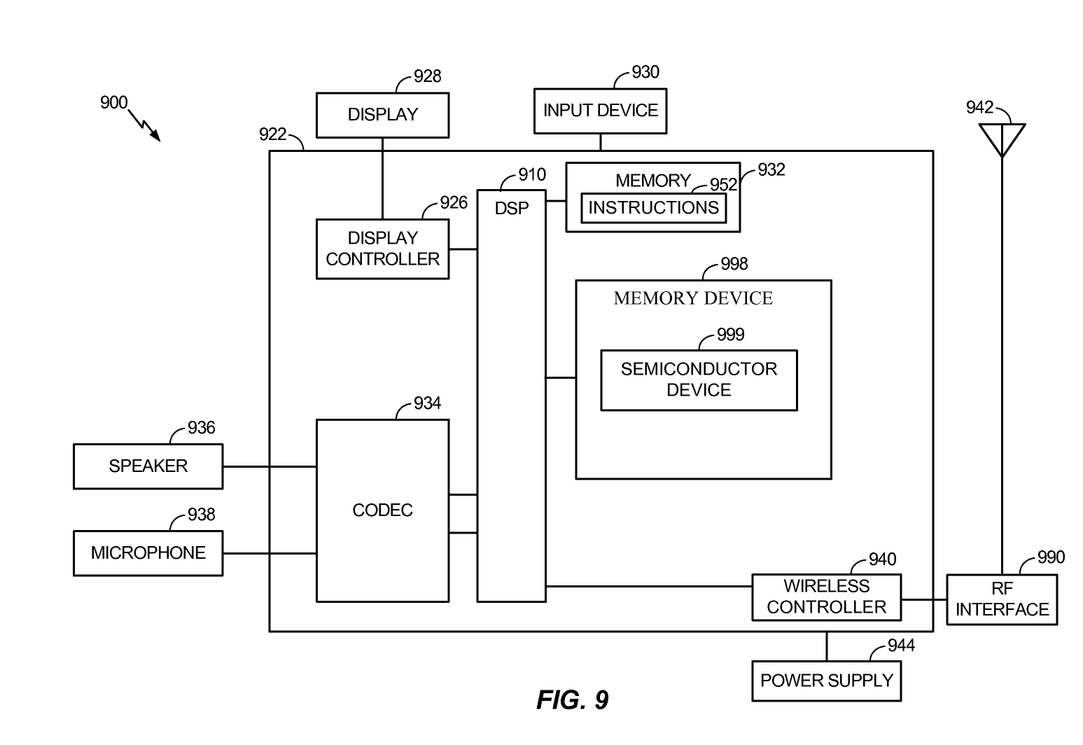

Referring to FIG. 9, a block diagram of a wireless device 900 including a semiconductor device 999 having a high resistance metal etch-stop plate to enable a metal flyover is shown. In a particular aspect, the semiconductor device 999 may be the semiconductor device 100 of FIG. 1, the semiconductor device 300 of FIG. 3, the semiconductor device 400 of FIG. 4, the semiconductor device 500 of FIG. 5, the semiconductor device 600 of FIG. 6, or the semiconductor device 700 of FIG. 7. The wireless device 900 includes a processor 910, such as a digital signal processor (DSP), coupled to a memory 932.

The memory 932 may be a non-transitory processor-readable storage medium that includes instructions 952. In a particular aspect, the processor 910 may include the semiconductor device 100 of FIG. 1, the semiconductor device 300 of FIG. 3, the semiconductor device 400 of FIG. 4, the semiconductor device 500 of FIG. 5, the semiconductor device 600 of FIG. 6, or the semiconductor device 700 of FIG. 7.

The wireless device 900 may also include a display controller 926 that is coupled to the processor 910 and to a display 928. A coder/decoder (CODEC) 934 can also be coupled to the processor 910. A speaker 936 and a microphone 938 can be coupled to the CODEC 934 and to the processor 910. FIG. 9 also indicates that a wireless controller 940 can be coupled to the processor 910. The wireless controller 940 may also be coupled to an antenna 942 via a radio frequency (RF) interface 990.

In a particular aspect, the processor 910, the display controller 926, the memory 932, the CODEC 934, and the wireless controller 940 are included in a system-in-package or system-on-chip device 922. In a particular aspect, an input device 930 and a power supply 944 are coupled to the system-on-chip device 922. Moreover, in a particular aspect, as illustrated in FIG. 9, the display 928, the input device 930, the speaker 936, the microphone 938, the antenna 942, and the power supply 944 are external to the system-on-chip device 922. However, each of the display 928, the input device 930, the speaker 936, the microphone 938, the antenna 942, and the power supply 944 can be coupled to a component of the system-on-chip device 922, such as an interface or a controller.

A memory device 998 may also be coupled to the processor 910. The memory device 998 may include the semiconductor device 999. In other particular aspects, other components of the wireless device 900 may include the semiconductor device 999. For example, the display controller 926, the display 928, the input device 930, the CODEC 934, the speaker 936, the microphone 938, the wireless controller 940, or any combination thereof, may include the semiconductor device 999.

In conjunction with the described aspects, an apparatus includes means for providing current to at least one of a source of a transistor or a drain of the transistor. The means for providing current may be positioned above at least one of the source of the transistor or the drain of the transistor. For example, the means for providing current may include the metal layer 134 of FIGS. 1, 3, 4, and 5.

The apparatus may also include means for providing etch protection to a metal gate of the transistor. The means for providing etch protection may be positioned between the metal gate of the transistor and the means for providing current. For example, the means for providing etch protection may include the high resistance metal etch-stop layer 132 of FIGS. 1, 3, 4, and 5.

The foregoing disclosed devices and functionalities may be designed and configured into computer files (e.g., RTL, GDSII, GERBER, etc.) stored on computer-readable media. Some or all such files may be provided to fabrication handlers to fabricate devices based on such files. Resulting products include wafers that are then cut into dies and packaged into chips. The chips are then employed in devices described above. FIG. 10 depicts a particular illustrative embodiment of an electronic device manufacturing process 1000.

Physical device information 1002 is received at the manufacturing process 1000, such as at a research computer 1006. The physical device information 1002 may include design information representing at least one physical property of a semiconductor device, such as a physical property of a device described with reference to FIGS. 1-7 and 9. For example, the physical device information 1002 may include physical parameters, material characteristics, and structure information that is entered via a user interface 1004 coupled to the research computer 1006. The research computer 1006 includes a processor 1008, such as one or more processing cores, coupled to a computer-readable medium such as a memory 1010. The memory 1010 may store computer-readable instructions that are executable to cause the processor 1008 to transform the physical device information 1002 to comply with a file format and to generate a library file 1012.

In a particular embodiment, the library file 1012 includes at least one data file including the transformed design information. For example, the library file 1012 may include a library of semiconductor devices, including a semiconductor device described with reference to FIGS. 1-7 and 9, provided for use with an electronic design automation (EDA) tool 1020.

The library file 1012 may be used in conjunction with the EDA tool 1020 at a design computer 1014 including a processor 1016, such as one or more processing cores, coupled to a memory 1018. The EDA tool 1020 may be stored as processor executable instructions at the memory 1018 to enable a user of the design computer 1014 to design a circuit including a semiconductor device described with reference to FIGS. 1-7 and 9, using the library file 1012. For example, a user of the design computer 1014 may enter circuit design information 1022 via a user interface 1024 coupled to the design computer 1014. The circuit design information 1022 may include design information representing at least one physical property of a semiconductor device, such as a semiconductor device described with reference to FIGS. 1-7 and 9. To illustrate, the circuit design property may include identification of particular circuits and relationships to other elements in a circuit design, positioning information, feature size information, interconnection information, or other information representing a physical property of an electronic device.

The design computer 1014 may be configured to transform the design information, including the circuit design information 1022, to comply with a file format. To illustrate, the file formation may include a database binary file format representing planar geometric shapes, text labels, and other information about a circuit layout in a hierarchical format, such as a Graphic Data System (GDSII) file format. The design computer 1014 may be configured to generate a data file including the transformed design information, such as a GDSII file 1026 that includes information describing a semiconductor device described with reference to FIGS. 1-7 and 9, in addition to other circuits or information. To illustrate, the data file may include information corresponding to a system-on-chip (SOC) or a chip interposer component that that includes a semiconductor device described with reference to FIGS. 1-7 and 9, and that also includes additional electronic circuits and components within the SOC.

The GDSII file 1026 may be received at a fabrication process 1028 to manufacture a semiconductor device described with reference to FIGS. 1-7 and 9 according to transformed information in the GDSII file 1026. For example, a device manufacture process may include providing the GDSII file 1026 to a mask manufacturer 1030 to create one or more masks, such as masks to be used with photolithography processing, illustrated in FIG. 10 as a representative mask 1032. The mask 1032 may be used during the fabrication process to generate one or more wafers 1033, which may be tested and separated into dies, such as a representative die 1036. The die 1036 includes a circuit including a semiconductor device described with reference to FIGS. 1-7 and 9.

In a particular embodiment, the fabrication process 1028 may be initiated by or controlled by a processor 1034. The processor 1034 may access a memory 1035 that includes executable instructions such as computer-readable instructions or processor-readable instructions. The executable instructions may include one or more instructions that are executable by a computer, such as the processor 1034.

The fabrication process 1028 may be implemented by a fabrication system that is fully automated or partially automated. For example, the fabrication process 1028 may be automated and may perform processing steps according to a schedule. The fabrication system may include fabrication equipment (e.g., processing tools) to perform one or more operations to form an electronic device. For example, the fabrication equipment may be configured to perform one or more of the processes described with reference to FIGS. 1-7 and 9 using integrated circuit manufacturing processes (e.g., wet etching, chemical vapor etching, dry etching, deposition, chemical vapor deposition, planarization, lithography, in-situ baking, or a combination thereof).

The fabrication system may have a distributed architecture (e.g., a hierarchy). For example, the fabrication system may include one or more processors, such as the processor 1034, one or more memories, such as the memory 1035, and/or controllers that are distributed according to the distributed architecture. The distributed architecture may include a high-level processor that controls or initiates operations of one or more low-level systems. For example, a high-level portion of the fabrication process 1028 may include one or more processors, such as the processor 1034, and the low-level systems may each include or may be controlled by one or more corresponding controllers. A particular controller of a particular low-level system may receive one or more instructions (e.g., commands) from a high-level system, may issue sub-commands to subordinate modules or process tools, and may communicate status data back to the high-level system. Each of the one or more low-level systems may be associated with one or more corresponding pieces of fabrication equipment (e.g., processing tools). In a particular embodiment, the fabrication system may include multiple processors that are distributed in the fabrication system. For example, a controller of a low-level system component of the fabrication system may include a processor, such as the processor 1034.

Alternatively, the processor 1034 may be a part of a high-level system, subsystem, or component of the fabrication system. In another embodiment, the processor 1034 includes distributed processing at various levels and components of a fabrication system.

The die 1036 may be provided to a packaging process 1038 where the die 1036 is incorporated into a representative package 1040. For example, the package 1040 may include the single die 1036 or multiple dies, such as a system-in-package (SiP) arrangement. The package 1040 may be configured to conform to one or more standards or specifications, such as Joint Electron Device Engineering Council (JEDEC) standards.

Information regarding the package 1040 may be distributed to various product designers, such as via a component library stored at a computer 1046. The computer 1046 may include a processor 1048, such as one or more processing cores, coupled to a memory 1050. A printed circuit board (PCB) tool may be stored as processor executable instructions at the memory 1050 to process PCB design information 1042 received from a user of the computer 1046 via a user interface 1044. The PCB design information 1042 may include physical positioning information of a packaged electronic device on a circuit board, the packaged electronic device corresponding to the package 1040 including a semiconductor device described with reference to FIGS. 1-7 and 9.

The computer 1046 may be configured to transform the PCB design information 1042 to generate a data file, such as a GERBER file 1052 with data that includes physical positioning information of a packaged electronic device on a circuit board, as well as layout of electrical connections such as traces and vias, where the packaged electronic device corresponds to the package 1040 including a semiconductor device described with reference to FIGS. 1-7 and 9. In other embodiments, the data file generated by the transformed PCB design information may have a format other than a GERBER format.

The GERBER file 1052 may be received at a board assembly process 1054 and used to create PCBs, such as a representative PCB 1056, manufactured in accordance with the design information stored within the GERBER file 1052. For example, the GERBER file 1052 may be uploaded to one or more machines to perform various steps of a PCB production process. The PCB 1056 may be populated with electronic components including the package 1040 to form a representative printed circuit assembly (PCA) 1058.

The PCA 1058 may be received at a product manufacturer 1060 and integrated into one or more electronic devices, such as a first representative electronic device 1062 and a second representative electronic device 1064. As an illustrative, non-limiting example, the first representative electronic device 1062, the second representative electronic device 1064, or both, may be selected from a set top box, a music player, a video player, an entertainment unit, a navigation device, a communications device, a personal digital assistant (PDA), a fixed location data unit, and a computer, into which a semiconductor device described with reference to FIGS. 1-7 and 9, is integrated. As another illustrative, non-limiting example, one or more of the electronic devices 1062 and 1064 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 10 illustrates remote units according to teachings of the disclosure, the disclosure is not limited to these illustrated units. Embodiments of the disclosure may be suitably employed in any device which includes active integrated circuitry including memory and on-chip circuitry.

A device that includes a semiconductor device described with reference to FIGS. 1-7 and 9, may be fabricated, processed, and incorporated into an electronic device, as described in the illustrative manufacturing process 1000. One or more aspects of the embodiments disclosed with respect to FIGS. 1-7 and 9 may be included at various processing stages, such as within the library file 1012, the GDSII file 1026, and the GERBER file 1052, as well as stored at the memory 1010 of the research computer 1006, the memory 1018 of the design computer 1014, the memory 1050 of the computer 1046, the memory of one or more other computers or processors (not shown) used at the various stages, such as at the board assembly process 1054, and also incorporated into one or more other physical embodiments such as the mask 1032, the die 1036, the package 1040, the PCA 1058, other products such as prototype circuits or devices (not shown), or any combination thereof. Although various representative stages are depicted with reference to FIGS. 1-7 and 9, in other embodiments fewer stages may be used or additional stages may be included. Similarly, the process 1000 of FIG. 10 may be performed by a single entity or by one or more entities performing various stages of the manufacturing process 1000.

In conjunction with the described aspects, an apparatus includes means for depositing a high resistance metal etch-stop layer above a metal gate of a transistor. The transistor may include a source and a drain. For example, the means for depositing the high resistance metal etch-stop layer may include one or more components of the manufacturing equipment in FIG. 10.

The apparatus also includes means for depositing a metal layer on the high resistance metal etch-stop layer. The metal layer may be positioned above at least one of the source of the transistor or the drain of the transistor. For example, the means for depositing the metal layer may include one or more components of the manufacturing equipment in FIG. 10.

Those of skill would further appreciate that the various illustrative logical blocks, configurations, modules, circuits, and algorithm steps described in connection with the aspects disclosed herein may be implemented as electronic hardware, computer software, or combinations of both. Various illustrative components, blocks, configurations, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the aspects disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary non-transitory (e.g. tangible) storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed aspects is provided to enable a person skilled in the art to make or use the disclosed aspects. Various modifications to these aspects will be readily apparent to those skilled in the art, and the principles defined herein may be applied to other aspects without departing from the scope of the disclosure. Thus, the present disclosure is not intended to be limited to the aspects shown herein but is to be accorded the widest scope possible consistent with the principles and novel features as defined by the following claims.

1. A semiconductor device comprising:
a transistor including a metal gate, a source, and a drain;
an inter-layer dielectric (ILD) at least partially overlying the metal gate of the transistor;
a silicon nitride (SiN) layer at least partially overlying the ILD;
a high resistance metal etch-stop layer at least partially overlying the SiN layer; and
a metal layer at least partially overlying the high resistance metal etch-stop layer, wherein the metal layer is positioned above at least one of the source of the transistor or the drain of the transistor.

2. The semiconductor device of claim 1, wherein the high resistance metal etch-stop layer is comprised of titanium nitride (TiN).

3. The semiconductor device of claim 1, wherein the metal layer is a flyover.

4. The semiconductor device of claim 3, wherein the high resistance metal etch-stop layer isolates the flyover from the metal gate.

5. The semiconductor device of claim 3, wherein the flyover is electrically coupled to the source or to the drain.

6. The semiconductor device of claim 3, wherein the flyover is electrically coupled to a second metal gate.

7. (canceled)

8. The semiconductor device of claim 1, wherein the high resistance metal etch-stop layer isolates the SiN layer from the metal layer.

9. A method comprising:
depositing an inter-layer dielectric (ILD) above a metal gate of a transistor, the transistor comprising a source and a drain;
depositing a silicon nitride (SiN) layer above the ILD;
depositing a high resistance metal etch-stop layer above the SiN; and
depositing a metal layer on the high resistance metal etch-stop layer, wherein the metal layer is positioned above at least one of the source of the transistor or the drain of the transistor.

10. The method of claim 9, wherein the high resistance metal etch-stop layer is comprised of titanium nitride (TiN).

11. The method of claim 9, wherein the metal layer is a flyover.

12. The method of claim 11, wherein the high resistance metal etch-stop layer isolates the flyover from the metal gate.

13. The method of claim 11, wherein the flyover is electrically coupled to the source or to the drain.

14. The method of claim 11, wherein the flyover is electrically coupled to a second metal gate.

15. (canceled)

16. The method of claim 9, wherein the high resistance metal etch-stop layer isolates the SiN layer from the metal layer.

17. A non-transitory computer-readable medium comprising data for enabling fabrication equipment to form a high resistance metal etch-stop layer for a metal layer, the data when used by the fabrication equipment, causes the fabrication equipment to:
initiate deposition of an inter-layer dielectric (ILD) above a metal gate of a transistor, the transistor comprising a source and a drain;
initiate deposition of a silicon nitride (SiN) layer above the ILD;
initiate deposition of the high resistance metal etch-stop layer above the SiN; and
initiate deposition of the metal layer on the high resistance metal etch-stop layer, wherein the metal layer is positioned above at least one of the source of the transistor or the drain of the transistor.

18. The non-transitory computer-readable medium of claim 17, wherein the high resistance metal etch-stop layer is comprised of titanium nitride (TiN).

19. The non-transitory computer-readable medium of claim 17, wherein the metal layer is a flyover.

20. The non-transitory computer-readable medium of claim 19, wherein the high resistance metal etch-stop layer isolates the flyover from the metal gate.

21. The non-transitory computer-readable medium of claim 19, wherein the flyover is electrically coupled to the source or to the drain.

22. The non-transitory computer-readable medium of claim 19, wherein the flyover is electrically coupled to a second metal gate.

23. (canceled)

24. The non-transitory computer-readable medium of claim 17, wherein the high resistance metal etch-stop layer isolates the SiN layer from the metal layer.

25. An apparatus comprising:
a transistor including a metal gate, a source, and a drain;
first means for providing current to the source of the transistor, wherein the first means for providing current at least partially overlies the source of the transistor;
second means for providing current to the drain of the transistor, wherein the second means for providing current at least partially overlies the drain of the transistor; and
means for providing etch protection to the metal gate of the transistor, the means for providing etch protection at least partially overlying the metal gate of the transistor, wherein a first portion of the means for providing etch protection at least partially underlies the first means for providing current, and wherein a second portion of the means for providing etch protection at least partially underlies the second means for providing current.

26. The apparatus of claim 25, wherein the means for providing etch protection is comprised of titanium nitride (TiN).

27. The apparatus of claim 25, wherein the first means for providing current is a first flyover, and wherein the second means for providing current is a second flyover.

28. The apparatus of claim 27, wherein the means for providing etch protection isolates the first flyover and the second flyover from the metal gate.

29. The apparatus of claim 27, wherein the first flyover is electrically coupled to the source, and wherein the second flyover is electrically coupled to the drain.

30. The apparatus of claim 27, wherein the first flyover is electrically coupled to a second metal gate, and wherein the second flyover is electrically coupled to a third metal gate.

31. The apparatus of claim 25, further comprising a silicon nitride (SiN) layer positioned between the metal gate and the means for providing etch protection.

32. The apparatus of claim 25, further comprising:
an inter-layer dielectric (ILD) positioned between the metal gate and a silicon nitride (SiN) layer, wherein the silicon nitride (SiN) layer is positioned between the ILD and the means for providing etch protection.

33. The apparatus of claim 25, further comprising an inter-layer dielectric (ILD) positioned on top of the means for providing etch protection and in between the first means for providing current and the second means for providing current.
